(19) United States
(12) Patent Application Publication
(10) Pub. No.: US 2015/0090336 A1
(43) Pub. Date: Apr. 2, 2015

(54) Organic-inorganic hybrid light emitting device, method for manufacturing the same, and organic-inorganic hybrid solar cell

(71) Applicant: University of Seoul Industry Cooperation Foundation, Seoul (KR)

(72) Inventors: Wan-Shick Hong, Seoul (KR); Tae-Ho Song, Seoul (KR)

(21) Appl. No.: 14/120,664

(22) Filed: Jun. 13, 2014

(30) Foreign Application Priority Data
Oct. 1, 2013 (KR) 10-2013-0117255

(51) Int. Cl. H01L 51/50; H01L 51/56; H01L 51/42

(52) U.S. Cl. CPC H01L 51/5012; H01L 51/4213; H01L 51/56
USPC 136/263; 257/40; 438/47

(57) ABSTRACT

The present invention provides an organic-inorganic composite light-emitting device including a luminescent layer emitting high-brightness light using low voltage, wherein the luminescent layer has a sandwich structure in which organic luminescent layers are formed on both sides of an inorganic thin film layer.

The organic-inorganic composite light-emitting device configured as above is advantageous in that an inorganic thin film layer is inserted and formed between organic luminescent layers, and thus the injection of electrons that occurs when low voltage is applied stabilizes the structure of the luminescent layer, thereby emitting brighter light. Further, the organic-inorganic composite light-emitting device is effective in greatly improving the power efficiency of an organic light-emitting device by greatly increasing the luminance efficiency thereof. Moreover, the organic-inorganic composite light-emitting device can exhibit improved luminance efficiency at low cost because it can be manufactured by directly using a conventional organic light-emitting device structure and a conventional process of manufacturing an organic light-emitting device.

### TECHNICAL FIELD

The present invention relates to a light-emitting device, and, more particularly, to a light-emitting device including a luminescent layer made of a laminate of an organic material and an inorganic material, and a manufacturing method thereof.

### BACKGROUND ART

Recently, with the advent of the information age, display technologies for visually expressing electrical information signals have been rapidly advanced. Accordingly, various flat-panel displays have been developed to rapidly replace conventional cathode ray tubes (CRTs).

Specific examples of such flat-panel displays may include liquid crystal displays (LCDs), organic light-emitting displays (OLEDs), electrophoretic displays (EPDs), electric paper displays, plasma display panels (PDPs), field emission displays (FEDs), electroluminescent displays (ELDs), and electro-wetting displays (EWDs).

Such flat-panel displays commonly include a flat display panel for realizing an image as an essential element. The flat display panel is configured such that a pair of substrates are aligned, so as to face each other, and are attached to each other with an intrinsic light-emitting material layer or polarizing material layer therebetween.

Among such flat-panel displays, an organic electroluminescent display is a display for displaying an image using an organic light-emitting device including positive and negative electrodes facing each other and a luminescent layer made of an organic luminous material and formed between the positive and negative electrodes.

In this case, such an organic light-emitting device is a self-luminous device configured such that, when holes and electrons are respectively transported from positive and negative electrodes subject to the application of forward voltage to a luminescent layer, exitons generated by recombination of the transported holes and electrons are dropped from an excited state to a ground state to generate energy, and the generated energy is converted into light having a predetermined wavelength band. Since such an organic light-emitting device can emit light having a specific color depending on the material constituting a luminescent layer, an organic electroluminescent display including a plurality of organic light-emitting devices emitting light having various colors has an advantage of realizing a color image without a color filter.

Consequently, since such an organic electroluminescent display, unlike a liquid crystal display (LCD) for displaying an image by adjusting the transmittance of external light or light emitted from a backlight unit, does not need an additional light source, it is advantageous in terms of miniaturization and thin film formation and has a wide view angle, compared to a liquid crystal display. Further, since such an organic electroluminescent display exhibits a response speed 1000 or more times as fast as that of a liquid crystal display, it has an advantage of no afterimage remaining. Thanks to the advantages of the organic electroluminescent display, it has been widely used in small displays, such as mobile communication terminals, personal information terminals, camcorders, digital cameras. However, to date, the application of the organic electroluminescent display has been restricted due to the limitation in performance of an organic light-emitting device, and thus efforts to improve the performance of the organic light-emitting device have continuously been made.

Meanwhile, in order to improve the performance of an organic light-emitting device, methods of using an organic light-emitting device together with an inorganic material have been researched.

For example, there was developed a hybrid light-emitting device including a polymer layer serving to transport holes and a fluorescent nanomaterial layer, which are sequentially formed on a PEDOT/PSS layer serving as a hole injection layer. However, this hybrid light-emitting device is disadvantageous in that fluorescent particles agglomerate in the process of applying the fluorescent nanomaterial layer using spin coating. Further, there was proposed a method of manufacturing an organic-inorganic hybrid electroluminescent device (Korean Patent Registration No. 10-1134913), wherein a fluorescent nanomaterial layer is directly formed of reactive ink injected from two or more heads, and simultaneously a hole injection layer surrounding the fluorescent nanomaterial layer is formed. However, the organic-inorganic hybrid electroluminescent device manufactured by this method is not a genuine organic-inorganic composite light-emitting device, and is disadvantageous in that conventional manufacturing processes and equipment cannot be used.

[Prior art document] Korean Patent Registration No. 10-1134913

### DISCLOSURE

### Technical Problem

Accordingly, the present invention has been made to solve the above-mentioned problems, and an object of the present invention is to provide a light-emitting device including an organic-inorganic composite luminescent layer emitting high-brightness light using low voltage, and a manufacturing method thereof.

### Technical Solution

In order to accomplish the above object, an aspect of the present invention provides an organic-inorganic composite light-emitting device, including: first and second electrodes facing each other; a luminescent layer formed between the first and second electrodes to emit light using a hole and an electron respectively injected from the first and second electrodes; a hole transfer layer formed between the first electrode and the luminescent layer to transfer the hole from the first electrode to the luminescent layer; and an electron transfer layer formed between the second electrode and the luminescent layer to transfer the electron from the second electrode to the luminescent layer, wherein the luminescent layer has a sandwich structure in which organic luminescent layers are formed on both sides of an inorganic thin film layer.

Here, the hole transfer layer may include: a hole injection layer being in contact with the first electrode to receive a hole from the first electrode; and a hole transport layer being in contact with the luminescent layer to transport the hole to the luminescent layer. Further, the electron transfer layer may include: an electron injection layer being in contact with the second electrode to receive an electron from the second electrode; and an electron transport layer being in contact with the luminescent layer to transport the electron to the luminescent layer.

Further, the inorganic thin film layer may be a nanocrystalline silicon thin film layer or a MoS₂ thin film layer.

Another aspect of the present invention provides a method of manufacturing the organic-inorganic composite light-emitting device, including the processes of sequentially forming a first electrode, a hole transfer layer, a luminescent layer, an electron transfer layer and a second electrode, wherein the process of forming the luminescent layer includes the steps of: forming an organic luminescent layer; forming an inorganic thin film layer on the organic luminescent layer; and forming another organic luminescent layer on the inorganic thin film layer.

Here, the process of forming the hole transfer layer may include the steps of: forming a hole injection layer on the first electrode; and forming a hole transport layer on the hole injection layer. Further, the process of forming the electron transfer layer may include the steps of: forming an electron transport layer on the luminescent layer; and forming an electron injection layer on the electron transport layer.

Further, in the step of forming the inorganic thin film layer, a nanocrystalline silicon thin film may be formed by catalytic chemical vapor deposition(Cat-CVD).

Further, in the step of forming the inorganic thin film layer, a MoS₂ thin film may be formed by a transfer method using cellophane tape.

Still another aspect of the present invention provides an organic-inorganic composite solar cell, including: a glass substrate; a transparent electrode layer formed on the glass substrate; a hole transport layer formed on the transparent electrode layer; a photoactive layer formed on the hole transport layer; and a metal electrode layer formed on the photoactive layer, wherein the photoactive layer has a sandwich structure in which organic photoactive layers are formed on both sides of an inorganic thin film layer.

The organic-inorganic composite solar cell may further include: an electron transport layer formed between the photoactive layer and the metal electrode layer.

### Advantageous Effects

The organic-inorganic composite light-emitting device configured as above is advantageous in that an inorganic thin film layer is inserted and formed between organic luminescent layers, and thus the injection of electrons that occurs when low voltage is applied stabilizes the structure of the organic luminescent layer, thereby emitting brighter light.

Further, the organic-inorganic composite light-emitting device is effective in greatly improving the power efficiency of an organic light-emitting device by greatly increasing the luminance efficiency thereof.

Moreover, the organic-inorganic composite light-emitting device can exhibit improved luminance efficiency at low cost because it can be manufactured by directly using a conventional organic light-emitting device structure and a conventional process of manufacturing an organic light-emitting device.

Meanwhile, the organic-inorganic composite solar cell configured as above is effective in greatly improving the efficiency of an organic solar cell by inserting and forming an inorganic thin film layer between organic photoactive layers.

### DESCRIPTION OF DRAWINGS

FIG. 1 is a schematic sectional view showing the laminate structure of an organic-inorganic composite light-emitting device according to an embodiment of the present invention.

FIG. 2 presents optical microscope photographs showing the MoS₂ flakes transferred on a silicon oxide thin film.

FIG. 3 is a schematic sectional view showing the laminate structure of a comparative organic light-emitting device.

FIG. 4 is a photograph of the organic-inorganic composite light-emitting device provided therein with a MoS₂ inorganic thin film layer according to an embodiment of the present invention, when a voltage of 10V was applied.

FIG. 5 is a photograph of the comparative organic light-emitting device, when a voltage of 10V was applied.

FIG. 6 is a graph showing the voltage-brightness relationship of the organic-inorganic composite light-emitting device according to an embodiment of the present invention and the comparative light-emitting device.

FIG. 7 is a graph showing the voltage-current relationship of the organic-inorganic composite light-emitting device according to an embodiment of the present invention and the comparative organic light-emitting device.

FIG. 8 is a two-dimensional CIE chromaticity diagram of the comparative organic light-emitting device.

FIG. 9 is a two-dimensional CIE chromaticity diagram of the organic-inorganic composite light-emitting device provided therein with a MoS₂ inorganic thin film layer according to an embodiment of the present invention.

FIG. 10 is a three-dimensional graph reconfigured by tracking the trajectory of color coordinates of FIG. 8 according to the applied voltage.

FIG. 11 is a three-dimensional graph reconfigured by tracking the trajectory of color coordinates of FIG. 9 according to the applied voltage.

FIG. 12 is a schematic sectional view showing the structure of an organic-inorganic composite solar cell according to an embodiment of the present invention.

### MODE FOR INVENTION

Hereinafter, preferred embodiments of the present invention will be described in detail with reference to the attached drawings.

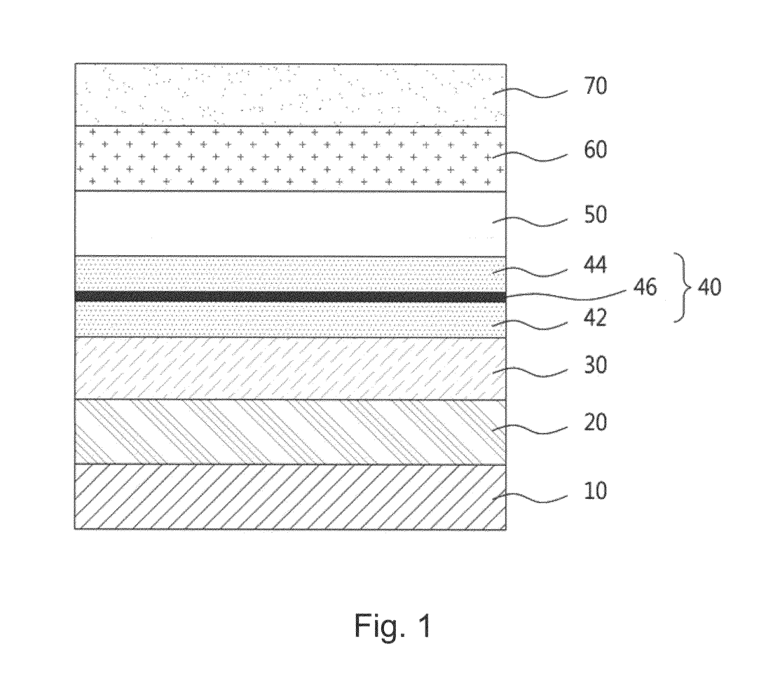

FIG. 1 is a schematic sectional view showing the laminate structure of an organic-inorganic composite light-emitting device according to an embodiment of the present invention.

The organic-inorganic composite light-emitting device according to an embodiment of the present invention includes a luminescent layer 40 disposed between a first electrode 10 and a second electrode 70 facing each other.

The organic-inorganic composite light-emitting device further includes: a hole injection layer 20 being in contact with the first electrode 10 to receive holes from the first electrode 10; and a hole transport layer 30, one side of which is in contact with the hole injection layer 20 and the other side of which is in contact with the luminescent layer 40, to transport the holes charged in the hole injection layer 20 to the luminescent layer 40, wherein each of the hole injection layer 20 and the hole transport layer 30 is a hole transfer layer for transferring the holes from the first electrode 10 to the luminescent layer 40.

Further, the organic-inorganic composite light-emitting device further includes: an electron injection layer 60 being in contact with the second electrode 70 to receive electrons from the second electrode 70; and an electron transport layer 50, one side of which is in contact with the electron injection layer 60 and the other side of which is in contact with the luminescent layer 40, to transport the electrons charged in the electron injection layer 60 to the luminescent layer 40, wherein each of the electron injection layer 60 and the electron transport layer 50 is an electron transfer layer for transferring the electrons from the second electrode 70 to the luminescent layer 40.

In this case, the luminescent layer 40 of the organic-inorganic composite light-emitting device has a sandwich structure in which organic luminescent layers 42 and 44 are formed on both sides of an inorganic thin film layer 46.

Among the constituents of the organic-inorganic composite light-emitting device according to an embodiment of the present invention, all the constituents, excluding the luminescent layer 40, are the same as those of a conventional light-emitting device. For this reason, conventional manufacturing processes and equipment may be directly used in the present invention, and thus detailed descriptions thereof will be omitted. Meanwhile, additional constituents for improving characteristics may be applied without limitation as long as they do not damage the structure of the luminescent layer 40.

Each of the organic luminescent layers 42 and 44 constituting the luminescent layer 40 may be made of a material used in an organic luminescent layer of a general organic light-emitting device. Further, the inorganic thin film layer 46 may be made of an inorganic material as long as it can be formed into a thin plate to be disposed between the organic luminescent layers 42 and 44. Particularly, the inorganic thin film layer 46 is advantageously formed when an inorganic material or an inorganic compound is composed of two-dimensional plate-like crystals to be easily stripped in the form of a thin plate. In the present invention, molybdenum disulfide (MoS₂), which has recently attracted considerable attention as an alternative to nanocrystalline silicon, is used as a raw material of the inorganic thin film layer 46.

Molybdenum disulfide (MoS₂) is in the limelight as a next-generation 2-D nanomaterial to replace graphene because it has a bandgap similar to that of amorphous or nanocrystalline silicon and is easily stripped in the form of a monolayer due to its layer structure.

Since the method of manufacturing the organic-inorganic composite light-emitting device of the present invention is similar to a method of manufacturing a general organic light-emitting device, a detailed description thereof will be omitted, and the formation of a luminescent layer will be described in detail.

The method of manufacturing an organic-inorganic composite light-emitting device according to an embodiment of the present invention is the same as a conventional method of manufacturing an organic light-emitting device in the point that the organic-inorganic composite light-emitting device is formed by sequentially laminating the constituents thereof from the first electrode 10 to the second electrode 70. In this method, a conventional manufacturing process is directly applied.

However, this method is different from the conventional method in the point that an organic luminescent layer 42 is first formed, an inorganic thin film layer 46 is formed on one side of the organic luminescent layer 42, and then an organic luminescent layer 44 is further formed on the one side of the inorganic thin film layer 46.

When nanocrystalline silicon is used as the raw material of the inorganic thin film layer 46, a nanocystalline silicon thin film may be formed by depositing monocrystalline silicon at a temperature of 900° C. or higher and crushing the deposited monocrystalline silicon or by catalytic chemical vapor deposition (Cat-CVD). In this embodiment, in order for MoS₂ to be used as the raw material of the inorganic thin film layer 46, MoS₂ flakes, obtained by stripping a multilayered MoS₂ film using a cellophane tape, are transferred to the surface of the organic luminescent layer 42.

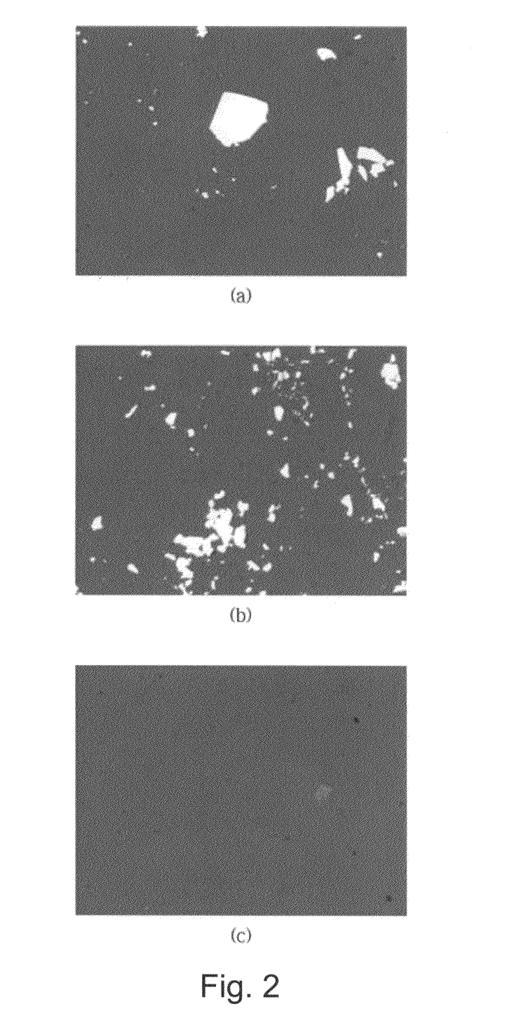

FIG. 2 presents optical microscope photographs showing the MoS₂ flakes transferred on a silicon oxide thin film.

Each of the optical microscope photographs shows MoS₂ flakes depending on the number of times of stripping the multilayered MoS₂ film using cellophane tape. (a) of FIG. 2 is an optical microscope photographs of MoS₂ flakes when the number of stripping times is 3, (b) of FIG. 2 is an optical microscope photographs of MoS₂ flakes when the number of stripping times is 4, and (c) of FIG. 2 is an optical microscope photographs of MoS₂ flakes when the number of stripping times is 6. As shown in FIG. 2, MoS₂ is transferred to a multilayered film when the number of stripping times is small, but a monolayer film is obtained when the number of stripping times is 6.

In order to evaluate the performance of the organic-inorganic composite light-emitting device according to an embodiment of the present invention, a comparative organic light-emitting device was manufactured.

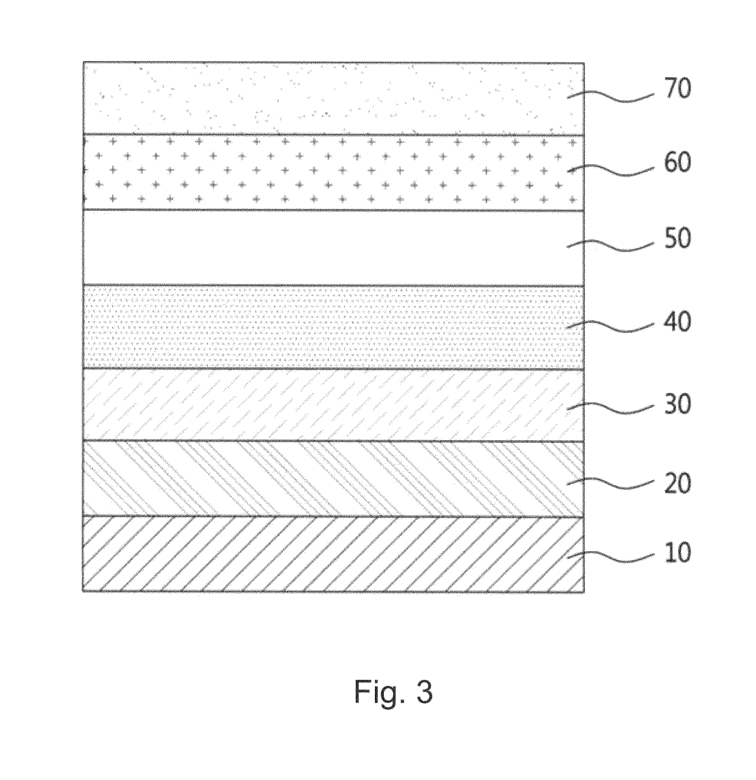

FIG. 3 is a schematic sectional view showing the laminate structure of a comparative organic light-emitting device.

The structure and the manufacturing process of the comparative organic light-emitting device is the same as the organic-inorganic composite light-emitting device according to an embodiment of the present invention, except for a luminescent layer 40. In the comparative organic light-emitting device, the luminescent layer 40 was formed by a single process such that its thickness is the same as the sum of thicknesses of the organic luminescent layers 42 and 44 of the organic-inorganic composite light-emitting device according to an embodiment of the present invention.

Voltage was respectively applied to the organic-inorganic composite light-emitting device provided therein with a MoS₂ inorganic thin film layer according to an embodiment of the present invention and the comparative organic light-emitting device to observe a luminous phenomenon.

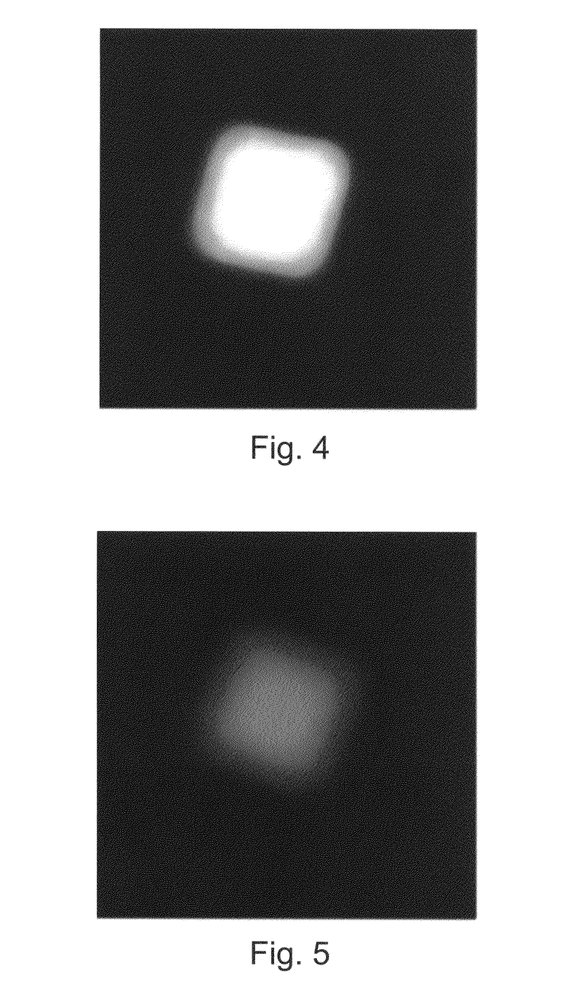

FIG. 4 is a photograph of the organic-inorganic composite light-emitting device provided therein with a MoS₂ inorganic thin film layer according to an embodiment of the present invention, when a voltage of 10V was applied, and FIG. 5 is a photograph of the comparative organic light-emitting device, when a voltage of 10V was applied.

As shown in FIGS. 4 and 5, it can be ascertained that, when the same voltage was applied, the brightness of the organic-inorganic composite light-emitting device provided therein with a MoS₂ inorganic thin film layer according to an embodiment of the present invention is outstanding, enough to distinguish by the naked eye.

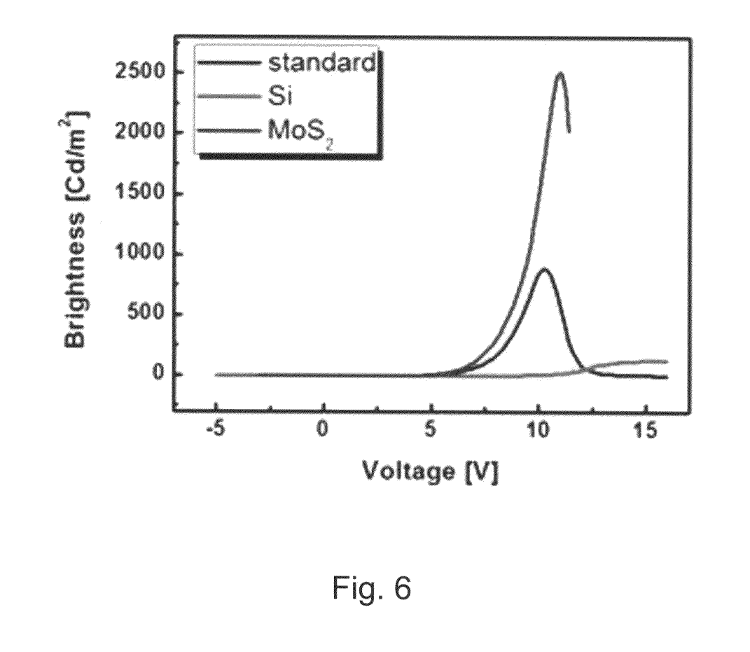

FIG. 6 is a graph showing the voltage-brightness relationship of the organic-inorganic composite light-emitting device according to an embodiment of the present invention and the comparative organic light-emitting device.

From FIG. 6, it can be ascertained that the organic-inorganic composite light-emitting device provided therein with a MoS₂ inorganic thin film layer according to an embodiment of the present invention, similarly to the comparative organic light-emitting device, starts to emit light at the same voltage, and its performance is not deteriorated by the existence of the MoS₂ inorganic thin film layer. In contrast, it can be ascertained that the peak thereof at the maximum brightness is about 2.5 times higher than that of the comparative organic light-emitting device.

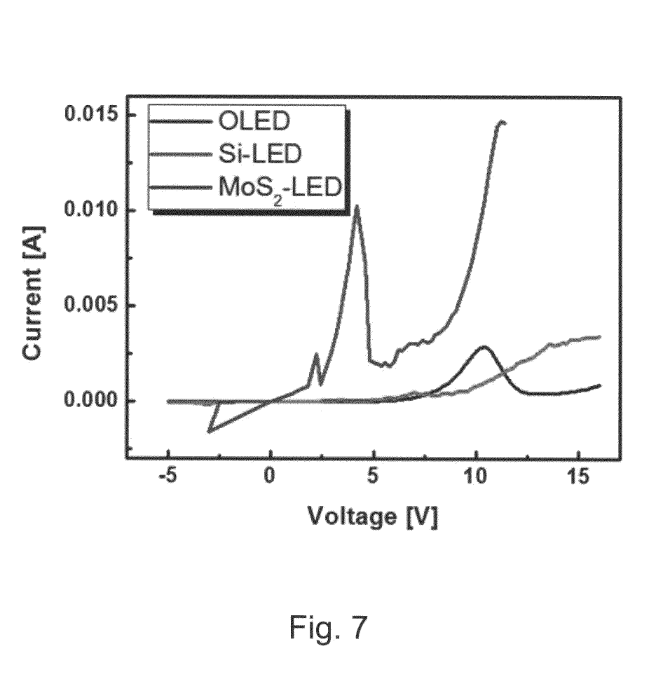

FIG. 7 is a graph showing the voltage-current relationship of the organic-inorganic composite light-emitting device according to an embodiment of the present invention and the comparative organic light-emitting device.

In the case of the organic-inorganic composite light-emitting device provided therein with a MoS₂ inorganic thin film layer according to an embodiment of the present invention, it was observed that current greatly increases at a low voltage and then decreases, and then the current increases again at a voltage at which light starts to emit. Since the structure of a luminescent layer of the organic-inorganic composite light-emitting device according to an embodiment of the present invention did not exist heretofore, the cause of such a phenomenon was not verified. However, it is presumed that the electric charges injected under a low voltage provides a kind of priming effect, that is, influences the bonding state between MoS₂ nanostructures and organic luminescent layers, thus increasing the brightness of the organic luminescent layer. The name of such an effect has not yet been specified, but it is referred to as “a priming effect” in the present specification.

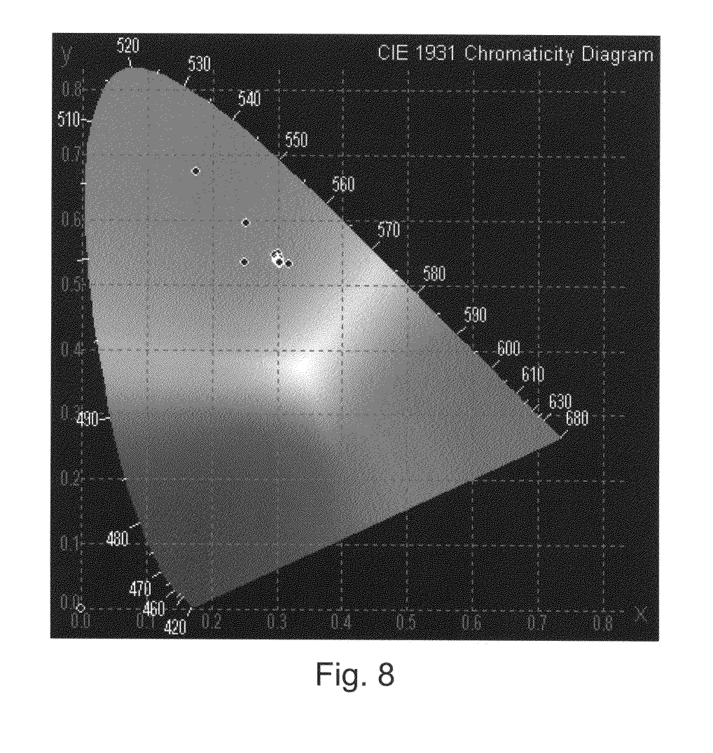

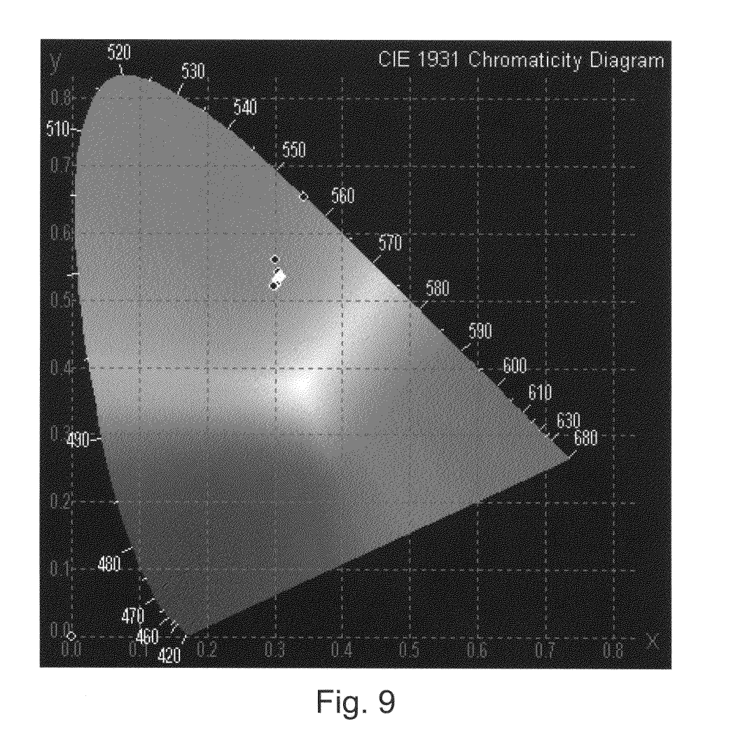

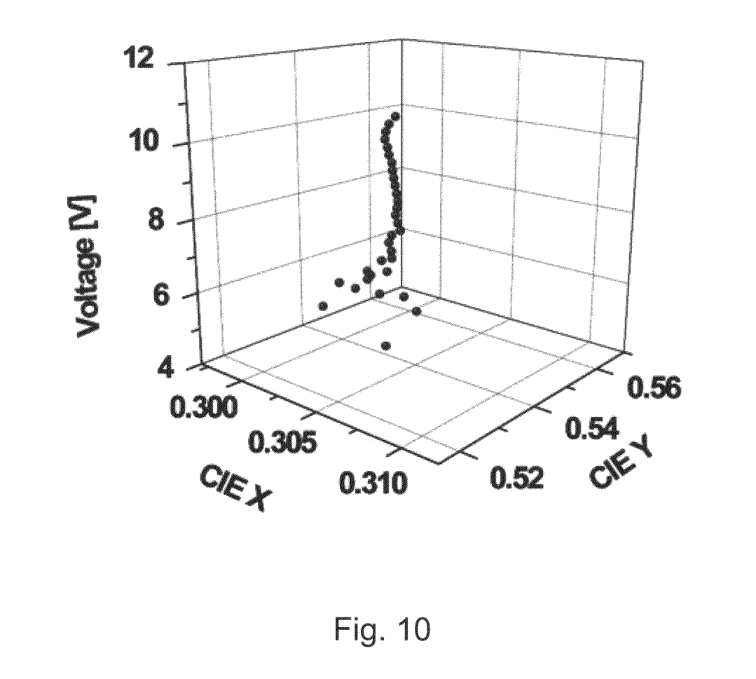

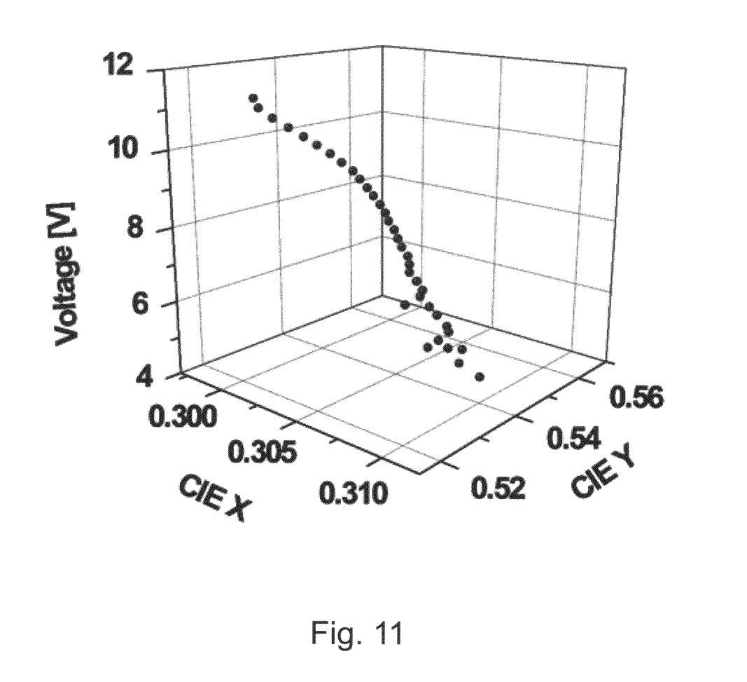

Meanwhile, FIGS. 8 and 9 are two-dimensional CIE chromaticity diagrams of the comparative organic light-emitting device and the organic-inorganic composite light-emitting device provided therein with a MoS₂ inorganic thin film layer according to an embodiment of the present invention, respectively. FIGS. 10 and 11 are three-dimensional graphs of the comparative organic light-emitting device and the organic-inorganic composite light-emitting device provided therein with a MoS₂ inorganic thin film layer according to an embodiment of the present invention, each of which is reconfigured by tracking the trajectory of color coordinates according to the applied voltage, respectively.

As shown in FIG. 8, the comparative organic light-emitting device emits light in a wide color coordinate range, but, as shown in FIG. 9, the organic-inorganic composite light-emitting device provided therein with a MoS₂ inorganic thin film layer according to an embodiment of the present invention emits light in a relatively narrow color coordinate range.

Meanwhile, as shown in FIG. 10, it was observed that, in the comparative organic light-emitting device, the irregular fluctuation of color coordinates occurred in a low voltage range. In contrast, as shown in FIG. 11, it was observed that, in the organic-inorganic composite light-emitting device provided therein with a MoS₂ inorganic thin film layer according to an embodiment of the present invention, color coordinates are shifted only in a Y-axis direction depending on the increase of applied voltage. However, as the three-dimensional diagram is shown on a two-dimensional plane, the change width of color coordinate in FIG. 11 seems to be larger than that in FIG. 10, but, as shown in FIG. 9, in actuality, the change width of color coordinate in FIG. 11, depending upon applied voltage, is the smallest.

The above results support the presumption that injected electric charges will exhibit the priming effect of stabilizing the structure of a luminescent layer when low voltage is applied to the organic-inorganic composite light-emitting device provided therein with a MoS₂ inorganic thin film layer, according to an embodiment of the present invention.

Further, this priming effect occurring in the luminescent layer of the organic-inorganic composite light-emitting device is also applied to an organic photoactive layer of an organic solar cell including a photoactive layer made of an organic material to improve the efficiency thereof. Therefore, an inorganic-organic composite solar cell can be manufactured using this organic-inorganic composite light-emitting device.

An organic solar cell, which is a solar cell including a light-absorbing layer made of an organic material, is advantageous in that an organic material is cheaper than an inorganic material such as silicon, and its manufacturing process is very simple, thus remarkably reducing the production cost thereof. An organic solar cell includes an organic material serving as an electron donor and an organic material serving as an electron acceptor. The operating principle of an organic solar cell is: when light is incident upon a photoactive layer made of an organic material, electrons are excited, and the excited electrons are weakly electrostatically bonded to holes remaining in the excited sites, thus forming excitons coupled to each other. In order for the excitons formed by solar light to produce a photocurrent, an electron-hole pair must be dissociated into an electron and a hole, and, in this case, electrons must move toward an anode, and holes must be moved toward a cathode.

Recently, with the technical advance of a polymer-made solar cell, the energy conversion efficiency thereof has been improved. In the polymer system generally used in an organic solar cell, a mixed solution of a conjugated polymer such as poly(3-hexylthiophene) (P3HT) and 6,6-phenyl-Cₓ-butyric acid methyl ester (PCₓBM) is used as an essential material.

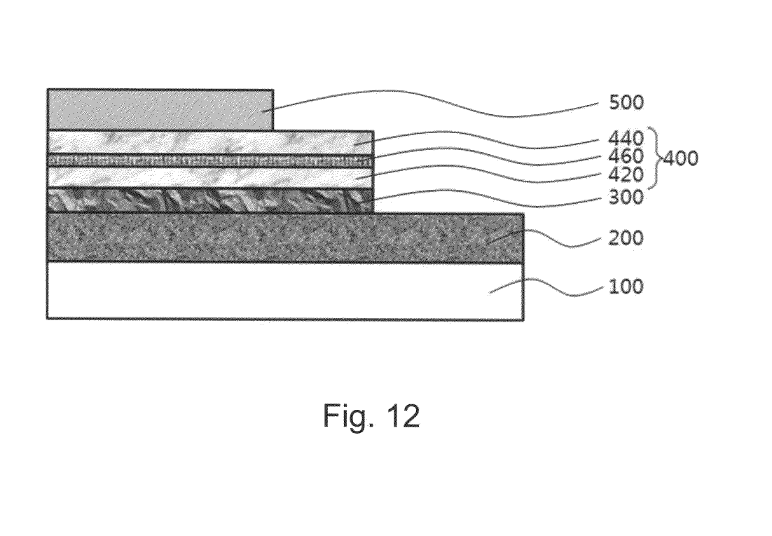

FIG. 12 is a schematic sectional view showing the structure of an organic-inorganic composite solar cell according to an embodiment of the present invention.

As shown in FIG. 12, the structure of the organic-inorganic composite solar cell according to an embodiment of the present invention is similar to that of a general organic solar cell in the point that a transparent electrode layer 200, a hole transport layer 300, a photoactive layer 400 and a metal electrode layer 500 are sequentially laminated on a glass substrate 100.

However, the photoactive layer 400 of the organic-inorganic composite solar cell has a sandwich structure in which organic photoactive layers 420 and 440 are formed on both sides of an inorganic thin film layer 460.

Among the constituents of the organic-inorganic composite solar cell according to an embodiment of the present invention, all the constituents, excluding the photoactive layer 400, are the same as those of a conventional organic solar cell. For this reason, conventional manufacturing processes and equipment may be directly used in the present invention, and thus detailed descriptions thereof will be omitted. Meanwhile, additional constituents for improving characteristics may be applied without limitation as long as they do not damage the structure of the photoactive layer 400. For example, the organic-inorganic composite solar cell may be configured such that an electron transport layer is additionally formed between the photoactive layer 400 and the metal electrode layer 500.

Each of the organic photoactive layers 420 and 440 constituting the photoactive layer 400 may be made of a material used in an organic photoactive layer of a general organic solar cell. Further, the inorganic thin film layer 460 may be made of an inorganic material as long as it can be formed into a thin plate. Particularly, the inorganic thin film layer 460 is advantageously formed when an inorganic material or an inorganic compound is composed of two-dimensional plate-like crystals to be easily stripped in the form of a thin plate.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention. Accordingly, any and all modifications, variations or equivalent arrangements should be considered to be within the scope of the invention, and the detailed scope of the invention will be disclosed by the accompanying claims.

1. An organic-inorganic composite light-emitting device, comprising:
first and second electrodes facing each other;
a luminescent layer formed between the first and second electrodes to emit light using a hole and an electron respectively injected from the first and second electrodes;
a hole transfer layer formed between the first electrode and the luminescent layer to transfer the hole from the first electrode to the luminescent layer; and
an electron transfer layer formed between the second electrode and the luminescent layer to transfer the electron from the second electrode to the luminescent layer,
wherein the luminescent layer has a sandwich structure in which organic luminescent layers are formed on both sides of an inorganic thin film layer.

2. The organic-inorganic composite light-emitting device of claim 1, wherein the hole transfer layer comprises:
a hole injection layer being in contact with the first electrode to receive a hole from the first electrode; and
a hole transport layer being in contact with the luminescent layer to transport the hole to the luminescent layer.

3. The organic-inorganic composite light-emitting device of claim 1, wherein the electron transfer layer comprises:
an electron injection layer being in contact with the second electrode to receive an electron from the second electrode; and
an electron transport layer being in contact with the luminescent layer to transport the electron to the luminescent layer.

4. The organic-inorganic composite light-emitting device of claim 1, wherein the inorganic thin film layer is a nanocrystalline silicon thin film layer or a MoS₂ thin film layer.

5. A method of manufacturing the organic-inorganic composite light-emitting device of claim 1, comprising the processes of sequentially forming a first electrode, a hole transfer layer, a luminescent layer, an electron transfer layer and a second electrode,
wherein the process of forming the luminescent layer comprises the steps of:
forming an organic luminescent layer;
forming an inorganic thin film layer on the organic luminescent layer; and
forming another organic luminescent layer on the inorganic thin film layer.

6. The method of claim 5, wherein the process of forming the hole transfer layer comprises the steps of: forming a hole injection layer on the first electrode; and forming a hole transport layer on the hole injection layer.

7. The method of claim 5, wherein the process of forming the electron transfer layer comprises the steps of: forming an electron transport layer on the luminescent layer; and forming an electron injection layer on the electron transport layer.

8. The method of claim 5, wherein, in the step of forming the inorganic thin film layer, a nanocrystalline silicon thin film is formed by catalytic chemical vapor deposition.

9. The method of claim 5, wherein, in the step of forming the inorganic thin film layer, a MoS₂ thin film is formed by a transfer method using cellophane tape.

10. An organic-inorganic composite solar cell, comprising:
a glass substrate;
a transparent electrode layer formed on the glass substrate;
a hole transport layer formed on the transparent electrode layer;
a photoactive layer formed on the hole transport layer; and
a metal electrode layer formed on the photoactive layer,
wherein the photoactive layer has a sandwich structure in which organic photoactive layers are formed on both sides of an inorganic thin film layer.

11. The organic-inorganic composite solar cell of claim 10, further comprising: an electron transport layer formed between the photoactive layer and the metal electrode layer.
